(19) United States
(12) Patent Application Publication
(10) Pub. No.: US 2003/0087535 A1
(43) Pub. Date: May 8, 2003

(54) Film coating formation method

(75) Inventor: Seiji Matsuura, Tokyo (JP)

Correspondence Address: FOLEY AND LARDNER, SUITE 500, 3000 K STREET NW, WASHINGTON, DC, 20007, US

(73) Assignee: NEC Electronics Corporation

(21) Appl. No.: 10/285,567

(22) Filed: Nov. 1, 2002

(30) Foreign Application Priority Data
Nov. 2, 2001 (JP) 2001-337836

(51) Int. Cl. H01L 21/31; B05D 3/12

(52) U.S. Cl. 438/782; 427/240

(57) ABSTRACT

In a lithography process in the fabrication of a semiconductor device, a resist liquid is sprayed onto a substrate having vias with an aspect ratio of at least 1 while spinning the substrate at a constant speed of rotation. The substrate is then rotated for a prescribed time at a speed of rotation that is less than the speed of rotation during spraying, whereby the fill factor in vias and the state of coating at via edges are adjusted. After undergoing this step, the substrate is rotated at a speed of rotation that is greater than the speed of rotation during spraying to determine the film thickness.

### BACKGROUND OF THE INVENTION

1. Field of the Invention

The present invention relates to a film coating formation method for forming a film coating on a substrate in a lithographic process when fabricating a semiconductor device, and more particularly to a film coating formation method for forming a film coating on a substrate by spraying a resist liquid while spinning the substrate, i.e., by dynamic coating.

2. Description of the Related Art

Forming an organic film coating on a substrate by spraying a liquid resist while spinning the substrate, i.e., by dynamic coating, in a lithography process is a known method in lithography in the fabrication of semiconductor devices. Referring now to FIG. 1, which is a graph showing a prior-art coating sequence in dynamic coating, the horizontal axis indicates time (s) and the vertical axis indicates the speed of rotation (rpm) of the substrate. In the dynamic coating shown in FIG. 1, the film thickness of the organic film coating that is formed is determined by the speed of rotation of the substrate in the main spinning stage that follows the stage of spraying the resist liquid. Uniformity of this film thickness is achieved by optimizing factors of the coating sequence such as the speed of rotation in the main spinning and the duration of spinning. A dummy substrate is normally used to carry out this optimization.

An actual device substrate contains vias that underlie the coated surface, these vias having a depth that is substantially equal to or greater than the thickness of the film coating. The hydrophilic degree (wettability) of the substrate surface differs greatly in the vicinity of micro vias. Further, the fill factor of the interior of a via and the coating state at the edges of a via varies widely depending on the dimensions and shape of the via pattern on the substrate. We refer here to FIGS. 2A-2D, which are vertical sections of a device substrate showing differences in the fill factor of a coating liquid for various types of via patterns. Compared to vias 3 of a fixed depth (FIG. 2A), the fill factor of a coating liquid is typically smaller when the diameter of vias 3 is greater (FIG. 2B), greater when the diameter of vias 3 is smaller (FIG. 2D), and greater when the pitch of vias 3 is wider (FIG. 2C).

In the prior art, obtaining a product having not only satisfactory film thickness on the substrate surface but also a satisfactory fill factor inside vias that underlie the coated surface and satisfactory coating state at via edges involved optimizing properties inherent to the organic film coating such as viscosity. In other words, the fill factor inside vias and the coating state at via edges in a coating method of the prior art were substantially influenced by the selection (tuning) of the material composition of the film coat.

However, substrates of logic devices in particular often have a variety of types and depths of via patterns, and a considerable amount of labor was necessary for selecting (tuning) the film coating materials for all of these different types of substrates.

### SUMMARY OF THE INVENTION

It is an object of the present invention to provide a film coating formation method that can obtain a product having a satisfactory fill factor inside vias and coating state at via edges without requiring extra labor.

The film coating formation method of the present invention presupposes a method of forming a film coating by spraying a resist liquid while spinning a substrate in a lithography process when fabricating a semiconductor device. The substrate to which this method is applied has a via pattern that underlies the coating surface, and the aspect ratio of vias (i.e., via depth/via diameter) is at least 1. In the method of the present invention, a coating liquid is sprayed onto the above-described substrate while spinning the substrate at a constant speed, the substrate is rotated for a prescribed time at a constant speed of rotation that is less than the speed of rotation during spraying, and the substrate is then rotated at a speed of rotation that is greater than the speed of rotation during spraying to determine the film thickness.

In the film coating formation method as described above, adjusting the time of rotation at a speed of rotation that is less than the speed of rotation during spraying enables modification of the fill factor inside vias and the coating state of via edges in accordance with logic device substrates having a variety of types of via patterns. The present invention therefore eliminates the need for tuning the materials of the film coating to obtain a product having satisfactory fill factor inside vias and coating state at via edges, and thus lightens the burden entailed by this tuning.

The above and other objects, features, and advantages of the present invention will become apparent from the following description with reference to the accompanying drawings, which illustrate examples of the present invention.

### BRIEF DESCRIPTION OF THE DRAWINGS

FIG. 1 is a graph showing the prior-art coating sequence in dynamic coating.

FIGS. 2A-2D are vertical sectional views of a device substrate showing differences in fill factors in various via patterns.

FIG. 3 is a graph showing the sequence for coating by means of an embodiment of the present invention.

FIG. 4 is a vertical sectional view of a substrate showing the state of a film coating that has been formed on a substrate in the Anti-Reflection Coating (ARC) coating process of a dual damascene-via first process.

FIGS. 5A and 5B are overhead photographs of a substrate when coating at a low-speed rotation speed R of 500 rpm and at three different low-speed rotation times t of 1 second, 3 seconds, and 5 seconds for a substrate surface having vias with a diameter of 200 nm and a depth of 1.2 μm.

FIG. 6 shows sectional photographs of a substrate when coating at a low-speed rotation speed R of 500 rpm and at three different low-speed rotation times t of 1 second, 3 seconds, and 5 seconds for a substrate surface having vias with a diameter of 200 nm and a depth of 1.2 μm.

### DETAILED DESCRIPTION OF THE PREFERRED EMBODIMENTS

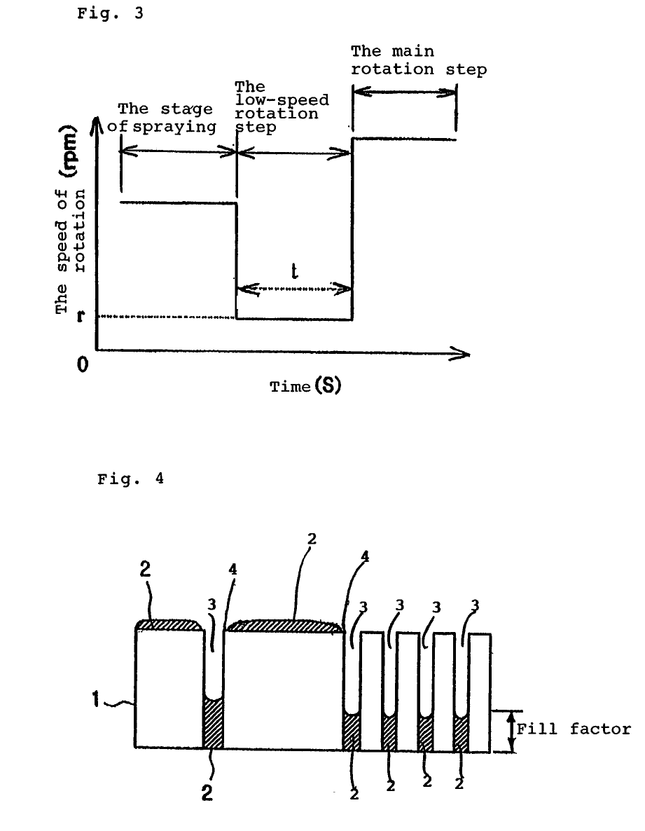

Embodiments of the film coating formation method of the present invention are next described for an actual case with reference to FIGS. 3-6.

The film coating formation method of the present embodiment is applied to a substrate having a via pattern that underlies a coating surface wherein the aspect ratio (i.e., via depth/via diameter) of these vias is at least 1. In addition, the film coating is an organic coat film.

FIG. 3 is a graph for explaining the film coating formation method of the present embodiment. In this figure, the horizontal axis shows time (s) and the vertical axis shows the speed of rotation (rpm). As shown in FIG. 3, the film coating formation method of the present embodiment is realized by sequentially carrying out: a spraying step for spraying a resist liquid while spinning the substrate at a constant speed; a low-speed rotation step for rotating the substrate for a prescribed time at a constant speed that is less than the speed of rotation during spraying; and a main rotation step for rotating the substrate at a speed that is greater than the speed of rotation during spraying to determine the film thickness.

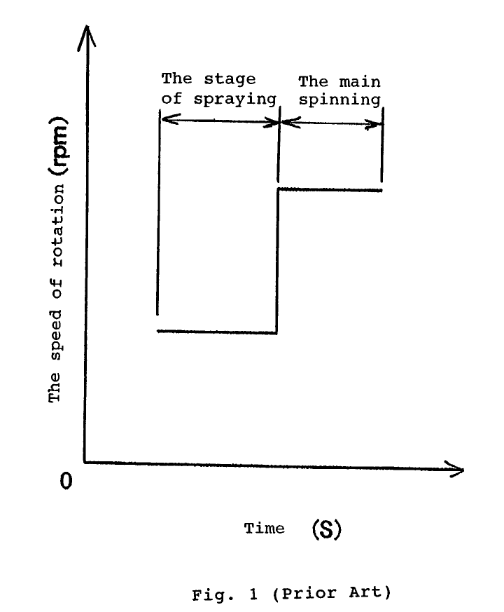

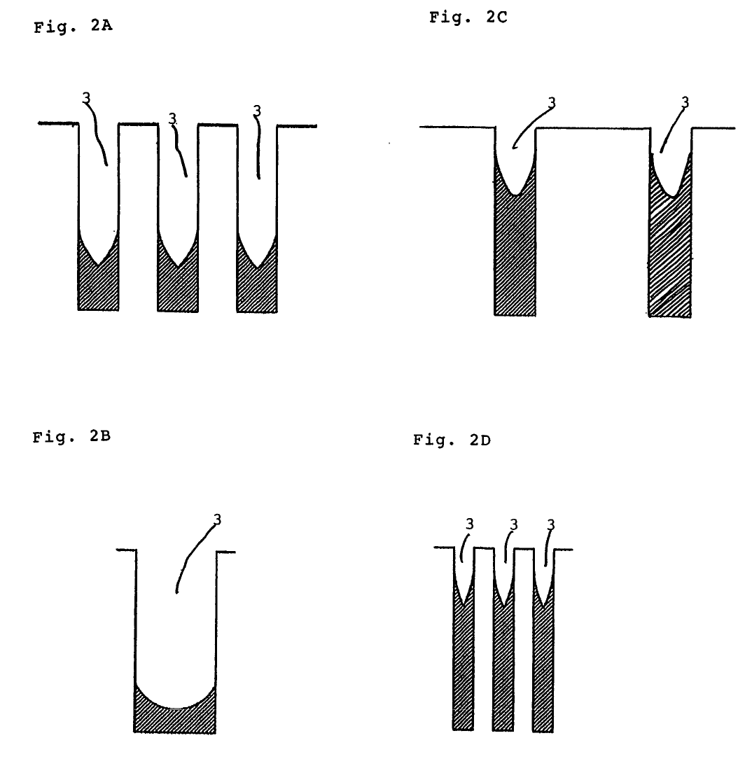

The speed of rotation r in the low-speed rotation step is less than 1000 rpm, and the time t of low-speed rotation is adjusted as appropriate in accordance with the fill characteristics inside vias and the coating characteristics at the edges of vias on the substrate that is being coated. The speed of spinning the substrate in the step for spraying resist liquid and the main rotation step is the same as the speed of rotation shown in FIG. 1.

When applied the film coating formation method of the present embodiment, the fill factor inside vias and the coating state of the edges of the vias can be modified by modifying the time of low-speed rotation t.

The reason for this is that although the main rotation step determines coating characteristic (i.e., the film thickness) chiefly in level areas of the substrate, the low-speed rotation step greatly influences the fill factor in vias and the coating state at via edges.

The anti-reflection coating (ARC) process of a dual damascene-via first process is next described as a representative example. FIG. 4 is a vertical section of a substrate showing the state of a film coating that has been formed on a substrate in this coating process. Explanation is here given regarding a case of partial-fill ARC in which vias are buried to a certain depth.

ARC 2 is coated on interlayer film 1 of the substrate as shown in FIG. 4. In this process, the issues are the control of the ability to coat ARC 2 as far as edges 4 of vias 3 on the surface of interlayer film 1 and the control of the fill factor while taking into consideration the dependence upon via dimensions (such as diameter and depth) and the pattern of arrangement of the vias.

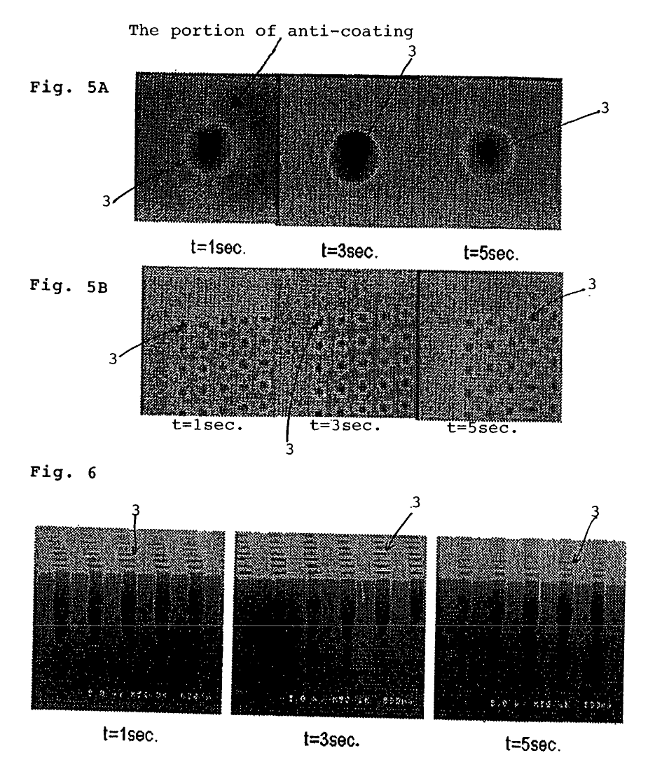

FIGS. 5A and 5B show overhead photographs and FIG. 6 shows sectional photographs of substrates when this ARC process is used to coat a substrate having vias with a diameter of 180 nm and a depth of 1.2 μm at a low-speed rotational speed r of 500 rpm and three low-speed rotation times t of 1 second, 3 seconds and 5 seconds. An increase in the low-speed rotation time t results in a proportional improvement in the coating characteristic of each via itself and at the edges of each via and for a via array, and as shown in FIG. 6, a proportional increase in fill factor, both in isolated vias (with a diameter of 180 nm) such as shown in FIG. 5A and in concentrated vias (with a diameter of 180 nm and a pitch of 400 nm) such as shown in FIG. 5B. The results of a close investigation by the applicant of the present application showed that low-speed rotation time t must be at least 3 seconds to obtain coating up to the edges of vias.

As described in the foregoing explanation, by applying the film coating formation method of the present invention, the fill characteristic of vias and the coating characteristic of the edges of vias can be modified by altering the low-speed rotation time. The reason for this is that, although the main rotation step determines the coating characteristics (i.e., film thickness) chiefly in level areas of the substrate surface, the low-speed rotation step greatly influences the fill factor inside vias and the coating characteristics of the substrate surface in the vicinity of via edges.

While a preferred embodiments of the present invention has been described using specific terms, such description is for illustrative purposes only, and it is to be understood that changes and variations may be made without departing from the spirit or scope of the following claims.

What is claimed is:

1. A film coating formation method for forming a film coating on a substrate in a lithography process in the fabrication of a semiconductor device, said method comprising the steps of:
preparing, as said substrate, a substrate having a via pattern that underlies the coating surface wherein the aspect ratio of vias (=via depth/via diameter) is at least 1;
spraying a resist liquid onto said substrate while spinning said substrate at a constant speed;
rotating said substrate for a prescribed time at a constant speed that is less than the speed of rotation during spraying; and
rotating said substrate at a speed of rotation that is greater than the speed of rotation during spraying to determine film thickness.

2. A film coating formation method according to claim 1, wherein said speed of rotation that is less than the speed of rotation during said spraying is less than 1000 revolutions per minute.

3. A film coating formation method according to claim 1, wherein said prescribed time is at least 3 seconds.

4. A film coating formation method according to claim 2, wherein said prescribed time is at least 3 seconds.

5. A film coating formation method according to claim 1, wherein said prescribed time is appropriately adjusted according to the fill characteristic in vias and the coating characteristic of via edges of said substrate.

6. A film coating formation method according to claim 2, wherein said prescribed time is appropriately adjusted according to the fill characteristic in vias and the coating characteristic of via edges of said substrate.
